(19) United States
(12) Patent Application Publication
(10) Pub. No.: US 2022/0314575 A1
(43) Pub. Date: Oct. 6, 2022

(54) METHOD FOR MANUFACTURING A DISPLAY DEVICE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Fei LI, Beijing (CN); Binfeng FENG, Beijing (CN); Zhihao XIE, Beijing (CN); Bowen XIAO, Beijing (CN)

(21) Appl. No.: 17/298,105

(22) PCT Filed: Sep. 30, 2020
(86) PCT No.: PCT/CN2020/119340

§ 371 Date: May 28, 2021

(51) Int. Cl. B32B 3/30; H05K 5/00; C09J 7/38; B32B 37/24; B32B 27/28; B32B 27/36; B32B 27/08

(52) U.S. Cl. CPC B32B 3/30; H05K 5/0017; C09J 7/381; B32B 37/24; B32B 27/281; B32B 27/36; B32B 27/08; C09J 2203/326; C09J 2301/416; C09J 2427/00; B32B 2457/20; B32B 2255/28; B32B 2255/26; B32B 2307/42; B32B 2037/243; B32B 2307/412

(57) ABSTRACT

The present disclosure relates to a method for manufacturing a display device and a display device. The method includes providing an unbent flexible layer, the flexible layer having a first side and a second side opposite to each other and further having a portion to be bent for forming a bent portion, applying a first curable layer on the first side of the portion to be bent, partially curing the first curable layer to form a first partially cured layer, applying and curing a second curable layer on the first partially cured layer to form a second cured layer, wherein a tack free time of the second curable layer is less than that of the first curable layer, disposing a first structural layer on the first side of the flexible layer, and bending the portion to be bent prior to the first partially cured layer is fully cured.

### CROSS-REFERENCE TO RELATED APPLICATIONS

The present application is the U.S. National Stage Entry of PCT/CN2020/119340, filed on Sep. 30, 2020, the entire disclosure of which is incorporated herein by reference as part of the disclosure of this application.

### TECHNICAL FIELD

The present disclosure relates to the technical field of displaying, and more particularly, to a method for manufacturing a display device and the display device.

### BACKGROUND

The design of mobile phone gradually expands towards the direction of foldable and narrow frame, which brings new challenges for the design of the mobile phone screen.

### SUMMARY

Embodiments of the present invention provide a method for manufacturing a display device.

The method for manufacturing a display device includes providing an unbent flexible layer, the flexible layer having a first side and a second side opposite to each other and further having a portion to be bent for forming a bent portion, applying a first curable layer on the first side of the portion to be bent, the first curable layer configured to adjust a position of a neutral layer of the portion to be bent during the portion to be bent is bent, partially curing the first curable layer to form a first partially cured layer, applying and curing a second curable layer on the first partially cured layer to form a second cured layer, wherein a tack free time of the second curable layer is less than a tack free time of the first curable layer, disposing a first structural layer on the first side of the flexible layer, the first structural layer covering at least a portion of the second cured layer, bending the portion to be bent of the flexible layer in a direction away from the first structural layer before the first partially cured layer is fully cured, thereby converting the portion to be bent into the bent portion, and curing the first partially cured layer to form a first fully cured layer.

In some embodiments, the first structural layer is in contact with the second curable layer.

In some embodiments, the flexible layer includes a functional layer located therein, wherein during the portion to be bent is bent, the neutral layer is configured such that the neutral layer is farther away from the second side compared with the functional layer.

In some embodiments, an elastic modulus of the second cured layer is greater than an elastic modulus of the first fully cured layer.

In some embodiments, a material of the first curable layer includes a photocurable material, and a material of the second curable layer includes a thermally curable material.

In some embodiments, the photocurable material includes an ultraviolet curable material, and the thermally curable material includes a fluoropolymer.

In some embodiments, a ratio of a thickness of the first fully cured layer to a thickness of the second cured layer is 10:1.

In some embodiments, a fully curing time of the first curable layer is greater than or equal to 120 hours, and wherein a tack free time of the second curable layer is less than or equal to 15 seconds.

In some embodiments, a curing rate of the first partially cured material is between 90% and 99%.

In some embodiments, the flexible layer includes a first flat portion and a second flat portion located on two sides of the portion to be bent, the first curable layer further covering edge portions, adjacent to the bent portion, of the first flat portion and the second flat portion.

In some embodiments, the flexible layer is a flexible display layer.

In some embodiments, the first side is a display side, and the second side is a non-display side. The method further includes disposing a second structural layer on the first side of the first flat portion prior to applying the first curable layer.

In some embodiments, the second structural layer includes a polarizing layer disposed on the first portion.

In some embodiments, the method further includes, prior to applying the first curable layer, disposing a first supporting layer on the second side of the first flat portion and disposing a second supporting layer on the second side of the second flat portion.

In some embodiments, the method further includes disposing a third structural layer on a side, away from the second side, of at least one of the first supporting layer and the second supporting layer prior to bending the portion to be bent of the flexible layer.

In some embodiments, the third structural layer includes a buffer layer on a side, away from the second side, of the first supporting layer, a heat dissipation layer on a side, away from the first supporting layer, of the buffer layer, and a spacer layer on a side, away from the buffer layer, of the heat dissipation layer.

In some embodiments, bending the portion to be bent of the flexible layer includes making the second side of the first flat portion of the flexible layer opposite to the second side of the second flat portion of the flexible layer.

In some embodiments, the display device includes a display region and a peripheral region adjacent to the display region, wherein the first flat portion is located in the display region and extends into the peripheral region, and the bent portion and the second flat portion are located in the peripheral region.

Embodiments of the present invention further provides a display device.

A display device according to an embodiment of the present invention includes a substrate having a first side and a second side opposite to the first side, a flexible layer having a bent portion and a first flat portion and a second flat portion located on two sides of the bent portion, wherein the first flat portion is located on the first side of the substrate, the second flat portion is located on the second side of the substrate, and the bent portion connects the first flat portion to the second flat portion, a first structural layer located on a side, away from the substrate, of the first flat portion, wherein a projection of the first structural layer on the substrate overlaps with a projection of the bent portion on the substrate, a first fully cured layer located on a side, away from the substrate, of the bent portion and configured to adjust a position of a neutral layer of the bent portion, wherein the first fully cured layer is formed by curing a first curable material, and a second cured layer formed on a side, away from the bent portion, of the first fully cured layer by curing a second curable material, wherein a tack free time of the second curable material is less than a tack free time of the first curable material.

In some embodiments, an elastic modulus of the second cured layer is greater than an elastic modulus of the first fully cured layer.

In some embodiments, a material of the first curable layer includes a photocurable material, and a material of the second curable layer includes a thermally curable material.

In some embodiments, the photocurable material includes an ultraviolet curable material, and the thermally curable material includes a fluoropolymer.

In some embodiments, a ratio of a thickness of the first fully cured layer to a thickness of the second cured layer is 10:1.

In some embodiments, the flexible layer is a flexible display layer.

In some embodiments, the display device further includes a second structural layer located between the first flat portion and the first structural layer.

In some embodiments, the second structural layer includes a polarizing layer.

In some embodiments, the substrate includes a buffer layer, a heat dissipation layer and a spacer layer which are sequentially disposed, wherein the buffer layer is adjacent to the first flat portion, and the spacer layer is adjacent to the second flat portion.

In some embodiments, the display device includes a display region and a peripheral region adjacent to the display region, wherein the first flat portion is located in the display region and extends into the peripheral region, and the bent portion and the second flat portion are located in the peripheral region.

### BRIEF DESCRIPTION OF THE DRAWINGS

In order to explain the technical solutions of the embodiments of the present disclosure more clearly, the drawings of the embodiments will be briefly described below. It should be understood that the drawings described below only relate to some embodiments of the present disclosure, instead of being a limit to the present disclosure, in which:

FIGS. 1A-1D are schematic views of a method for manufacturing a display device;

FIGS. 2A-2F are schematic views of a method for manufacturing a display device according to an embodiment of the present disclosure;

FIG. 3A is a schematic view of a position of a neutral layer of a portion to be bent prior to applying a first curable material layer;

FIG. 3B is a schematic view of the position of the neutral layer of the bent portion after bending;

FIG. 4 is a schematic view of a method for manufacturing a display device according to an embodiment of the present disclosure;

FIG. 5 is a schematic view of a method for manufacturing a display device according to an embodiment of the present disclosure;

FIG. 6 is a schematic view of a display device according to an embodiment of the present disclosure;

FIG. 7 is a schematic view of a display device according to an embodiment of the present disclosure.

### DETAILED DESCRIPTION

In order to make the objectives, technical solutions, and advantages of the embodiments of the present disclosure clearer, the technical solutions of the embodiments of the present disclosure will be described clearly and completely in conjunction with the accompanying drawings. Obviously, the described embodiments are part of the embodiments of the present disclosure, rather than all of the embodiments. Based on the described embodiments of the present disclosure, all other embodiments obtained by those skilled in the art without creative labor are also belonging to the protection scope of the present disclosure.

When the elements and the embodiments thereof of the present application are introduced, the articles “a/an”, “one”, “the” and “said” are intended to represent the existence of one or more elements. The expressions “comprise”, “include”, “contain” and “have” are intended as inclusive and mean that there may be other elements besides those listed.

For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on ” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected with or without any additional elements at the interface of the two elements.

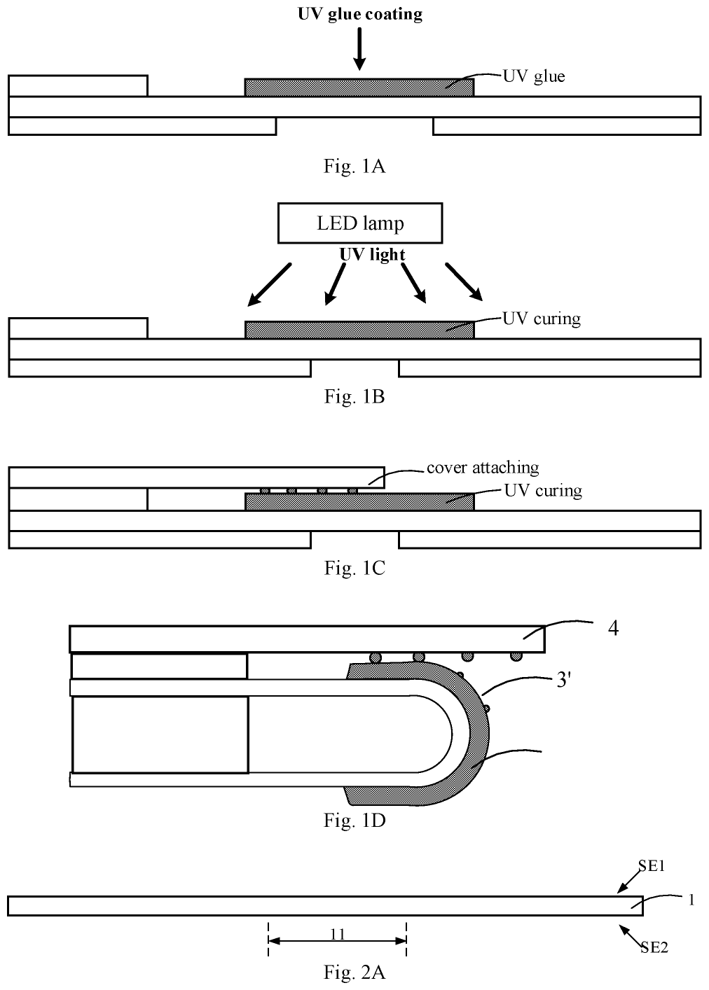

FIGS. 1A-1D are schematic views of a method for manufacturing a display device. As shown in FIGS. 1A-1D, the method includes coating an ultraviolet glue on a portion to be bent of a flexible layer, irradiating the ultraviolet glue with ultraviolet light to cure the ultraviolet glue, and then attaching a cover. The ultraviolet glue is typically thick and easily in contact with the cover. The time for fully curing the ultraviolet glue is long. The ultraviolet glue hasn't been fully cured prior to bending the flexible layer. In this way, the contact between the ultraviolet glue and the cover leads to the adhesion between them. When bending the portion to be bent, the ultraviolet glue and the cover will be separated from each other, and residual ultraviolet glue will remain on a surface of the cover facing the flexible layer. In addition, due to the adhesion between the ultraviolet glue and the cover, the separation will further pull and damage the ultraviolet glue layer and/or the flexible layer.

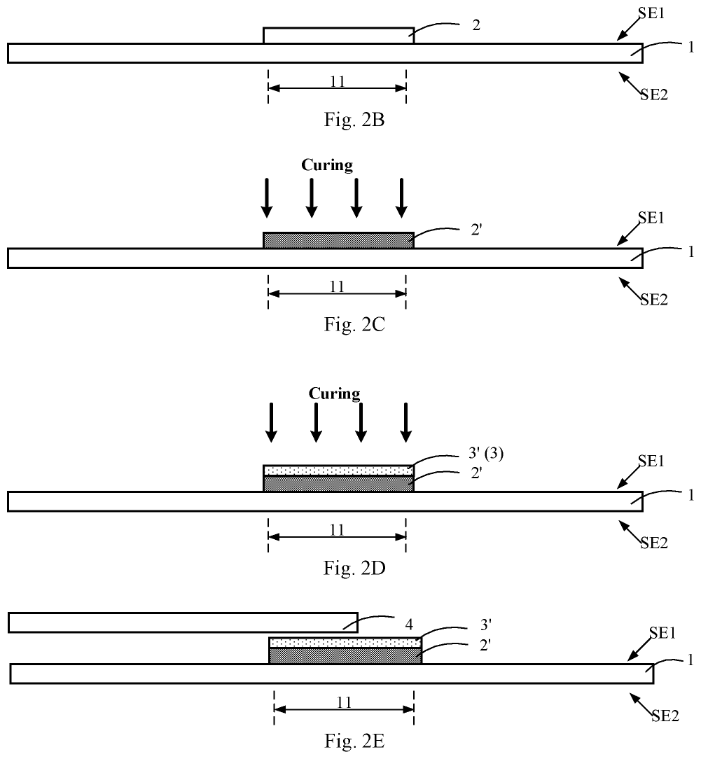

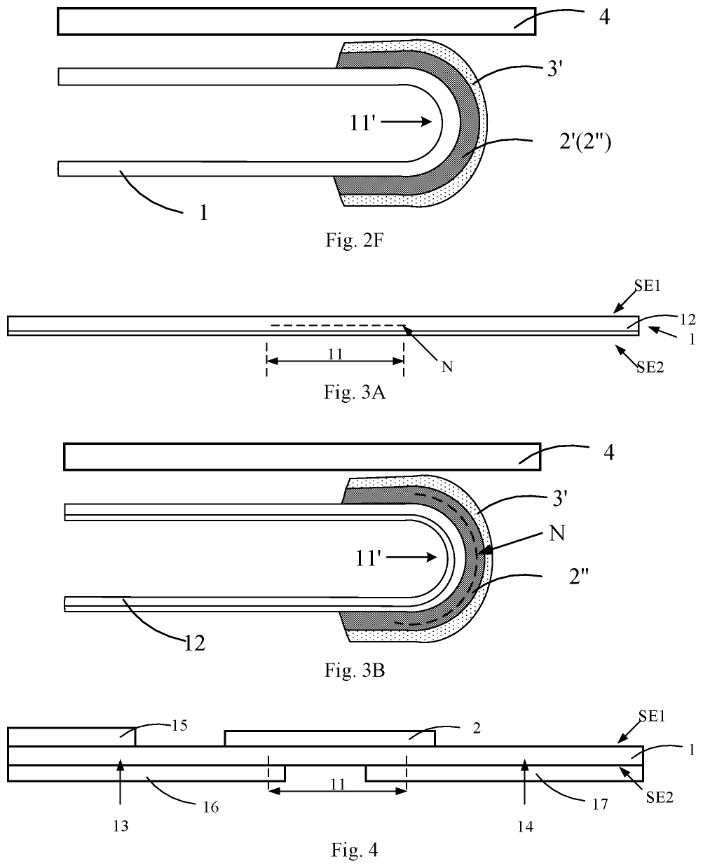

FIGS. 2A-2F are schematic views of a method for manufacturing a display device according to an embodiment of the present disclosure.

As shown in FIGS. 2A-2F, the method for manufacturing a display device according to an embodiment of the present disclosure includes :

S1. As shown in FIG. 2A, an unbent flexible layer 1 is provided. The flexible layer 1 has a first side SE1 and a second side SE2 opposite to each other and further has a portion to be bent 11 for forming a bent portion. It should be understood that, although in the drawings, the portion to be bent 11 is disposed in the middle of the flexible layer, the portion to be bent may be disposed at any position of the flexible layer according to actual needs. For example, the portion to be bent 11 may be disposed in an edge region. In the case where the flexible layer is implemented as a display layer, the portion to be bent 11 may be disposed in the middle position of the flexible layer, so as to facilitate the formation of a folded display device or a double-sided display device by bending the portion to be bent. In addition, the portion to be bent 11 may be disposed in the edge region, so that a flexible circuit board or a display driving IC connected with an end portion of the flexible layer can be bent to the non-display side of the flexible layer after bending, thereby realizing the narrow-frame design of the display.

S3. As shown in FIG. 2B, a first curable layer 2 is applied to the first side SE1 of the portion to be bent 11. The first curable layer 2 is configured to adjust positions of a neutral layer in the portion to be bent and in the bent portion formed by the portion to be bent. In mechanics of materials, when a structure A with a multi-layer configuration is bent and deformed, some layers are elongated and deformed, and other layers are compressed and deformed. At the interface between the elongated layer and the compressed layer, a layer without elongation deformation and compression deformation is called the neutral layer of the structure A.

S5. As shown in FIG. 2C, the first curable layer 2 is partially cured to form a first partially cured layer 2′. The curing conditions herein may be set as desired. For example, if the first curable layer includes a photocurable material, a corresponding curing light may be irradiated for curing. According to an embodiment of the present disclosure, the first curable layer may include an ultraviolet curable material. If the first curable layer includes a thermally curable material, the curing may be performed by heating.

S7. As shown in FIG. 2D, a second curable layer 3 is applied on the first partially cured layer 2′ and cured to form a second cured layer 3′. A tack free time of the second curable layer 3 is less than that of the first curable layer 2. The tack free time herein refers to the time required for fully curing a surface portion of material.

S9. As shown in FIG. 2E, a first structural layer 4 is disposed on the first side SE1 of the flexible layer 1. The first structural layer 4 covers at least a portion of the second cured layer 3′. In the present disclosure, the first structural layer 4 may contact the second cured layer 3′ at the portion to be bent 11.

S11. Prior to the first partially cured layer 2′ is fully cured, the portion to be bent 11 of the flexible layer 1 is bent in a direction away from the first structural layer 4, thereby converting the portion to be bent 11 into a bent portion 11′.

S13. The first partially cured layer 2′ is cured to form a first fully cured layer 2″. It should be noted that a portion of the first partially cured layer 2′ may be naturally cured to form the first fully cured layer 2″ without necessarily requiring an intentional curing process. In an embodiment of the present disclosure, the second curable layer having a faster tack free time is provided on the first curable layer such that the surface of the second curable layer is more quickly cured than the surface of the first curable layer. Even if the second curable layer is in contact with the first structural layer, the second curable layer can be prevented from adhering to the first structural layer since the second curable layer has a faster tack free rate. Thus, no foreign matter will be generated on the first structural layer after the flexible layer is bent, and the first cured layer and/or the flexible layer and the first structural layer will not be damaged.

In some embodiments, the flexible layer 1 may include a functional layer 12 located therein. Wherein during bending of the portion to be bent, the neutral layer is configured such that the neutral layer is farther away from the second side with respect to the functional layer. In the present disclosure, a functional layer refers to a structural layer for implementing at least one of a desired electrical function and an optical function. In other words, the functional layer may include corresponding electrical structures (e.g., circuits or wiring structures) or optical structures (e.g., grating structure, polarization structure, or lens structure).

FIG. 3A is a schematic view of a position of the neutral layer of the portion to be bent prior to applying the first curable material layer. As shown in FIG. 3A, the neutral layer N of the portion to be bent 11 prior to bending is located in the flexible layer 1, for example, in the functional layer 12. The functional layer 12 may include a conductive layer. For example, regarding to a case where the flexible layer includes a flexible display layer, the conductive layer may serve as a conductive wiring for the edge region of the flexible display layer. It should be noted that, in FIG. 3A, while the functional layer 12 is the outermost layer of the flexible layer 1, the functional layer 12 may also be the middle layer of the flexible layer 1 rather than the outermost layer.

FIG. 3B is a schematic view of the position of the neutral layer of the bent portion after bending. As shown in FIG. 3B, the position of the neutral layer N of the bent portion 11 after bending changes. The position of the neutral layer N of the bent portion 11 after introducing the curing layer is farther away from the second side of the flexible layer than without applying any curing layer. Although FIG. 3B shows that the neutral layer N is located in the second fully cured layer 2″, the position of the neutral layer N may be adjusted as needed. For example, the position of the neutral layer N may also be located at the interface between the flexible layer 1 and the second fully cured layer 2″, or still located in the flexible layer 1.

According to an embodiment of the present disclosure, in the case where the functional layer 12 includes a conductive wiring, since the conductive wiring is typically not composed of an organic material which causes that the conductive wiring is relatively resistant to compression but not resistant to elongating, the position of the neutral layer N is adjusted to be farther away from the second side, so that the functional layer 12 in the bent state is in a compressed state rather than an elongated state, thereby improving the life and stability of the display device.

In some embodiments, the elastic modulus of the second cured layer 3′ is greater than the elastic modulus of the first fully cured layer 2″. This will reduce the thickness of the first fully cured layer on the premise of maintaining the neutral layer in the same desired position, such that the sum of the thickness of the second cured layer and the first fully cured layer is less than the thickness of the first fully cured layer in the case where only the first fully cured layer is present. Thus, the thickness of the entire film layer at the bent region can be reduced generally.

In some embodiments, the material of the first curable layer may include a photocurable material. For example, the material of the first curable layer may include an ultraviolet curable material. The ultraviolet curable material may include ultraviolet glue. Curing the first curable layer may include curing with ultraviolet radiation (e.g., LED lamps).

In some embodiments, the material of the second curable layer may include a thermally curable material. The thermally curable material may include a fluoropolymer. For example, a fluorinated liquid of HYSTIC SP4235 type may be employed.

The fully curing time of the first curable layer, such as ultraviolet glue, after the first curable layer is irradiated by ultraviolet light is greater than or equal to 120 hours, while the tack free time of the second curable layer, such as the fluorinated liquid, is less than or equal to 15 seconds. By using a material with short tack free time as the surface material, it is beneficial to shorten the drying time required for forming a dry surface, thereby reducing the process time. In addition, the fluoropolymer has good chemical stability after being cured, and has good toughness and bending resistance.

Furthermore, the accuracy for disposing the fluorinated liquid is higher compared to coating ultraviolet glue. The tolerance for coating the ultraviolet glue tends to be about 30 μm, and the tolerance for disposing the fluorinated liquid may reach to about 2 μm. In this way, the thickness of the cured layer can be better controlled, which helps to avoid undesirable adhesion between the cured layer and the first structural layer located thereon.

In some embodiments, the first structural layer 4 may be a capping layer. The capping layer may include a flexible colorless polyimide (CPI) material or a flexible transparent polyimide material. The CPI material is relatively easy to adhere to the cured material and is easy to elongate and deform. The embodiment of the present disclosure can avoid the problem of adhesion between the capping layer and the cured material, and can also address the problem of the capping layer being elongated and deformed due to the adhesion when it is bent.

In some embodiments, the curing rate of the first partially cured material is between 90% and 99%. The ratio of the thickness of the first fully cured layer to the thickness of the second cured layer may be 10:1.

FIG. 4 is a schematic view of a method for manufacturing a display device according to an embodiment of the present disclosure. As shown in FIG. 4, the flexible layer 1 used as the display layer may also include a first flat portion 13 and a second flat portion 14 located on two sides of the portion to be bent 11. The first curable layer 2 also covers edge portions, adjacent to the bent portion, of the first flat portion and the second flat portion.

In some embodiments, the first side SE1 may be a display side and the second side SE2 may be a non-display side. The method for manufacturing a display device according to an embodiment of the present disclosure further includes disposing a second structure 15 on a first side of the first flat portion prior to applying the first curable layer. The second structure 15 may include a polarizer.

In some embodiments, the method for manufacturing a display device according to an embodiment of the present disclosure further includes disposing a first supporting layer 16 on a second side SE2 of the first flat portion 13 and disposing a second supporting layer 17 on a second side SE2 of the second flat portion 14 prior to applying the first curable layer. The first supporting layer 16 and the second supporting layer 17 are used to support the flexible layer, the material of which may include polyethylene terephthalate (PET) or polyimide (PI).

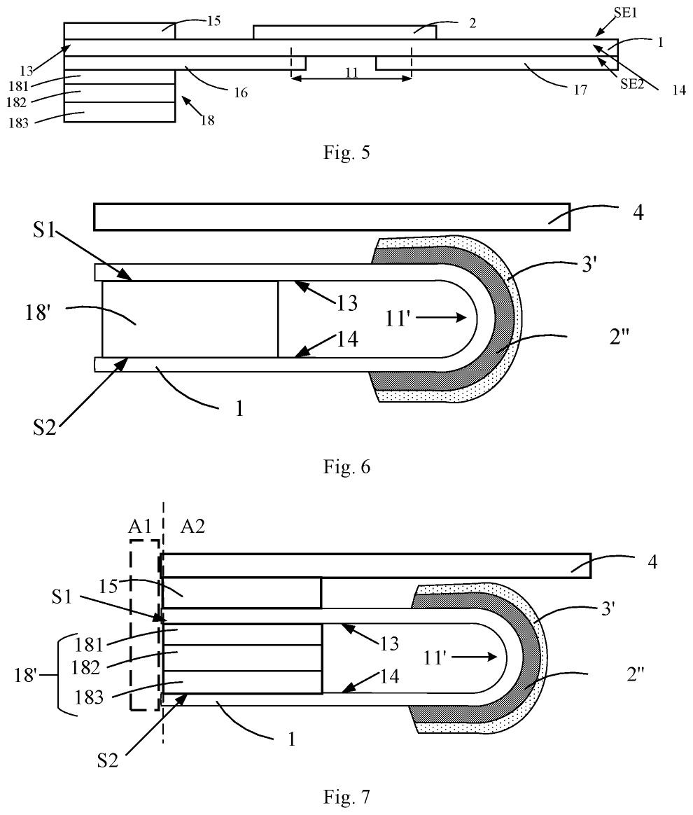

FIG. 5 is a schematic view of a method for manufacturing a display device according to an embodiment of the present disclosure. As shown in FIG. 5, the method for manufacturing a display device according to an embodiment of the present disclosure further includes disposing a third structural layer 18 on a side, away from the second side SE2, of at least one of the first supporting layer and the second supporting layer prior to bending the portion to be bent of the flexible layer.

In some embodiments, the third structural layer 18 may include a buffer layer 181 on a side, away from the second side SE2, of the first support 16, a heat dissipation layer 182 on a side, away from the second side SE2, of the buffer layer 181, and a spacer layer 183 on a side, away from the second side SE2, of the heat dissipation layer 182.

In some embodiments, the portion to be bent of the flexible layer is bent such that a second side SE2 of the first flat portion 16 of the flexible layer 1 is opposite to a second side SE2 of the second flat portion 17 of the flexible layer.

FIG. 6 is a schematic view of a display device according to an embodiment of the present disclosure. As shown in FIG. 6, the display device according to an embodiment of the present disclosure includes a substrate 18′ having a first side S1 and a second side S2 opposite to the first side S1, and a flexible layer 1. The flexible layer has a bent portion 11′ and a first flat portion 13 and a second flat portion 14 located on two sides of the bent portion 11′. The first flat portion 13 is located on the first side S1 of the substrate 18′, and the second flat portion 14 is located on the second side S2 of the substrate 18′. The bent portion 11′ connects the first flat portion 13 to the second flat portion 14. The display device according to an embodiment of the present disclosure further includes a first structural layer 4 located on a side, away from the substrate 14, of the first flat portion 13, wherein a projection of the first structural layer 4 on the substrate 18′ overlaps with a projection of the bent portion 11′ on the substrate 18′ in a direction perpendicular to the substrate 18′; a first fully cured layer 2″ located on a side, away from the substrate, of the bend portion 11′ and configured to adjust a position of a neutral layer of the bend portion, wherein the first fully cured layer is formed by curing a first curable material; and a second cured layer 3′ on a side, away from the bend portion 11′, of the first fully cured layer 2″, wherein the second cured layer formed by curing a second curable material, and wherein a tack free time of the second curable material is less than a tack free time of the first curable material. It should be noted that the “overlap” herein may refer to a full overlap and may also refer to a partial overlap.

As described in the method part of the preceding description, the elastic modulus of the second cured layer may be greater than the elastic modulus of the first fully cured layer. The material of the first curable layer may include a photocurable material, and the material of the second curable layer may include a thermally curable material. The photocurable material may include an ultraviolet curing material, and the thermally curable material may include a fluoropolymer. For example, the UV curing material may include ultraviolet glue, and the second curable material may include a fluorinated liquid.

In some embodiments, the ratio of the thickness of the first fully cured layer 3′ to the thickness of the second cured layer 2′ may be 10:1.

FIG. 7 is a schematic view of a display device according to an embodiment of the present disclosure. As shown in FIG. 7, the display device according to an embodiment of the present disclosure may further include a second structural layer 15 disposed on a side, away from the first side S1 of the substrate 18′, of the first flat portion 13. The flexible layer 1 may be a flexible display layer. The second structural layer 15 may include a polarizer. The substrate 18′ may include a buffer layer 181, a heat dissipation layer 182, and a spacer layer 183 which are sequentially disposed. The buffer layer 181 is adjacent to the first flat portion 13. The spacer layer 183 is adjacent to the second flat portion 14 and is in contact with a surface, toward the structural layer, of the second flat portion 14.

The display device according to an embodiment of the present invention includes a display region A1 and a peripheral region A2 adjacent to the display region. The first flat portion is located in the display region A1 and extends into the peripheral region A2, and the bent portion 11′ and the second flat portion 14 are located in the peripheral region A2.

Certain specific embodiments have been described, and these embodiments are only shown by way of example and are not intended to limit the scope of the present disclosure. In fact, the novel embodiments described herein can be implemented in various other forms; in addition, various omissions, substitutions and changes in the form of the embodiments described herein can be made without departing from the spirit of the present disclosure . The appended claims and their equivalents are intended to cover such forms or modifications that fall within the scope and spirit of the present disclosure.

What is claimed is:

1. A method for manufacturing a display device, comprising:
providing an unbent flexible layer, the flexible layer having a first side and a second side opposite to each other and further having a portion to be bent for forming a bent portion;
applying a first curable layer on the first side of the portion to be bent, the first curable layer configured to adjust a position of a neutral layer of the portion to be bent during the portion to be bent is bent;
partially curing the first curable layer to form a first partially cured layer;
applying and curing a second curable layer on the first partially cured layer to form a second cured layer, wherein a tack free time of the second curable layer is less than a tack free time of the first curable layer;
disposing a first structural layer on the first side of the flexible layer, the first structural layer covering at least a portion of the second cured layer;
bending the portion to be bent of the flexible layer in a direction away from the first structural layer before the first partially cured layer is fully cured, thereby converting the portion to be bent into the bent portion; and
curing the first partially cured layer to form a first fully cured layer.

2. The method according to claim 1, wherein an elastic modulus of the second cured layer is greater than an elastic modulus of the first fully cured layer.

3. The method according to claim 2, wherein the first curable material comprises an ultraviolet curable material, and the second curable material comprises a fluoropolymer.

4. The method according to claim 3, wherein a fully curing time of the first curable layer is greater than or equal to 120 hours, and wherein the tack free time of the second curable layer is less than or equal to 15 seconds.

5. The method according to claim 4, wherein the flexible layer comprises a first flat portion and a second flat portion located on two sides of the portion to be bent, the first curable layer further covering edge portions, adjacent to the bent portion, of the first flat portion and the second flat portion.

6. The method according to claim 5, further comprising prior to applying the first curable layer, disposing a first supporting layer on the second side of the first flat portion and disposing a second supporting layer on the second side of the second flat portion.

7. The method according to claim 6, further comprising prior to bending the portion to be bent of the flexible layer, disposing a third structural layer on a side, away from the second side, of at least one of the first supporting layer and the second supporting layer.

8. The method according to claim 7, wherein the third structural layer comprises a buffer layer on a side, away from the second side, of the first supporting layer, a heat dissipation layer on a side, away from the first supporting layer, of the buffer layer, and a spacer layer on a side, away from the buffer layer, of the heat dissipation layer, and wherein bending the portion to be bent of the flexible layer comprising making the second side of the first flat portion of the flexible layer opposite to the second side of the second flat portion of the flexible layer.

9. A display device, comprising:
a substrate having a first side and a second side opposite to the first side;
a flexible layer having a bent portion and a first flat portion and a second flat portion located on two sides of the bent portion, wherein the first flat portion is located on the first side of the substrate, the second flat portion is located on the second side of the substrate, and the bent portion connects the first flat portion to the second flat portion;
a first structural layer located on a side, away from the substrate, of the first flat portion, wherein a projection of the first structural layer on the substrate overlaps with a projection of the bent portion on the substrate;
a first fully cured layer located on a side, away from the substrate, of the bent portion and configured to adjust a position of a neutral layer of the bent portion, wherein the first fully cured layer is formed by curing a first curable material; and
a second cured layer formed on a side, away from the bent portion, of the first fully cured layer by curing a second curable material, wherein a tack free time of the second curable material is less than a tack free time of the first curable material.

10. The display device according to claim 9, wherein an elastic modulus of the second cured layer is greater than an elastic modulus of the first fully cured layer.

11. The display device according to claim 10, wherein a material of the first curable layer comprises a photocurable material, and a material of the second curable layer comprises a thermally curable material.

12. The display device according to claim 11, wherein the photocurable material comprises an ultraviolet curable material, and the thermally curable material comprises a fluoropolymer.

13. The display device according to claim 12, wherein a ratio of a thickness of the first fully cured layer to a thickness of the second cured layer is 10:1.

14. The display device according to claim 9, wherein the flexible layer is a flexible display layer.

15. The display device according to claim 14, further comprising a second structural layer located between the first flat portion and the first structural layer.

16. The display device according to claim 15, wherein the second structural layer comprises a polarizing layer.

17. The display device according to claim 9, wherein the substrate comprises a buffer layer, a heat dissipation layer and a spacer layer which are sequentially disposed, wherein the buffer layer is adjacent to the first flat portion, and the spacer layer is adjacent to the second flat portion.

18. The display device according to claim 9, wherein the display device comprises a display region and a peripheral region adjacent to the display region, wherein the first flat portion is located in the display region and extends into the peripheral region, and the bent portion and the second flat portion are located in the peripheral region.
